(19) United States
(12) Patent Application Publication
(10) Pub. No.: US 2014/0145332 A1
(43) Pub. Date: May 29, 2014

(54) METHODS OF FORMING GRAPHENE LINERS AND/OR CAP LAYERS ON COPPER-BASED CONDUCTIVE STRUCTURES

(71) Applicant: GLOBALFOUNDRIES INC., Grand Cayman (KY)

(72) Inventors: Errol T. Ryan, Clifton Park, NY (US); Zoran Krivokapic, Santa Clara, CA (US); Xunyuan Zhang, Albany, NY (US); Christian Witt, Woodbridge, CT (US); Ming He, Slingerlands, NY (US); Larry Zhao, Hoeilaart (BE)

(73) Assignee: GLOBALFOUNDRIES INC., Grand Cayman (KY)

(21) Appl. No.: 13/684,871

(22) Filed: Nov. 26, 2012

(51) Int. Cl. H01L 21/768; H01L 23/48

(52) U.S. Cl. CPC H01L 21/76843; H01L 23/481
USPC 257/751; 438/653

(57) ABSTRACT

One illustrative method disclosed herein includes forming a trench/via in a layer of insulating material, forming a graphene liner layer in at least the trench/via, forming a copper-based seed layer on the graphene liner layer, depositing a bulk copper-based material on the copper-based seed layer so as to overfill the trench/via, and performing at least one chemical mechanical polishing process to remove at least excess amounts of the bulk copper-based material and the copper-based seed layer positioned outside of the trench/via to thereby define a copper-based conductive structure with a graphene liner layer positioned between the copper-based conductive structure and the layer of insulating material.

### BACKGROUND OF THE INVENTION

1. Field of the Invention

Generally, the present disclosure relates to the manufacture of sophisticated semiconductor devices, and, more specifically, to various methods of forming graphene liners and/or capping layers on copper-based conductive structures.

2. Description of the Related Art

The fabrication of advanced integrated circuits, such as CPUs, storage devices, ASICs (application specific integrated circuits) and the like, requires a large number of circuit elements, such as transistors, capacitors, resistors, etc., to be formed on a given chip area according to a specified circuit layout. During the fabrication of complex integrated circuits using, for instance, MOS (Metal-Oxide-Semiconductor) technology, millions of transistors, e.g., N-channel transistors (NFETs) and/or P-channel transistors (PFETs), are formed on a substrate including a crystalline semiconductor layer. A field effect transistor, irrespective of whether an NFET transistor or a PFET transistor is considered, typically includes doped source and drain regions that are formed in a semiconducting substrate and separated by a channel region. A gate insulation layer is positioned above the channel region and a conductive gate electrode is positioned above the gate insulation layer. By applying an appropriate voltage to the gate electrode, the channel region becomes conductive and current is allowed to flow from the source region to the drain region.

In a field effect transistor, the conductivity of the channel region, i.e., the drive current capability of the conductive channel, is controlled by a gate electrode formed adjacent to the channel region and separated therefrom by a thin gate insulation layer. The conductivity of the channel region, upon formation of a conductive channel due to the application of an appropriate control voltage to the gate electrode, depends on, among other things, the dopant concentration, the mobility of the charge carriers and, for a given extension of the channel region in the transistor width direction, the distance between the source and drain regions, which is also referred to as the channel length of the transistor. Thus, in modern ultra-high density integrated circuits, device features, like the channel length, have been steadily decreased in size to enhance the performance of the semiconductor device and the overall functionality of the circuit. For example, the gate length (the distance between the source and drain regions) on modern transistor devices has been continuously reduced over the years and further scaling (reduction in size) is anticipated in the future. This ongoing and continuing decrease in the channel length of transistor devices has improved the operating speed of the transistors and integrated circuits that are formed using such transistors. However, there are certain problems that arise with the ongoing shrinkage of feature sizes that may at least partially offset the advantages obtained by such feature size reduction. For example, as the channel length is decreased, the pitch between adjacent transistors likewise decreases, thereby increasing the density of transistors per unit area. This scaling also limits the size of the conductive contact elements and structures, which has the effect of increasing their electrical resistance. In general, the reduction in feature size and increased packing density makes everything more crowded on modern integrated circuit devices, at both the device level and within the various metallization layers.

Improving the functionality and performance capability of various metallization systems has also become an important aspect of designing modern semiconductor devices. One example of such improvements is reflected in the increased use of copper metallization systems in integrated circuit devices and the use of so-called “low-k” dielectric materials (materials having a dielectric constant less than about 3) in such devices. Copper metallization systems exhibit improved electrical conductivity as compared to, for example, prior metallization systems that used tungsten for the conductive lines and vias. The use of low-k dielectric materials tends to improve the signal-to-noise ratio (S/N ratio) by reducing cross-talk as compared to other dielectric materials with higher dielectric constants. However, the use of such low-k dielectric materials can be problematic as they tend to be less resistant to metal migration as compared to some other dielectric materials.

Copper is a material that is difficult to etch using traditional masking and etching techniques. Thus, conductive copper structures, e.g., conductive lines or vias, in modern integrated circuit devices are typically formed using known single or dual damascene techniques. In general, the damascene technique involves (1) forming a trench/via in a layer of insulating material, (2) depositing one or more relatively thin barrier or liner layers (e.g., TiN, Ta, TaN), (3) forming copper material across the substrate and in the trench/via, and (4) performing a chemical mechanical polishing process to remove the excess portions of the copper material and the barrier layer(s) positioned outside of the trench/via to define the final conductive copper structure. The copper material is typically formed by performing an electrochemical copper deposition process after a thin conductive copper seed layer is deposited by physical vapor deposition on the barrier layer.

Unfortunately, it is becoming more difficult to satisfy the ongoing demand for smaller and smaller conductive lines and conductive vias for a variety of reasons. One such problem with traditional barrier layer materials, e.g., tantalum, tantalum nitride, ruthenium, is the minimum thickness to which those materials must be formed so that they can be formed as continuous layers and perform their intended functions. Thus, having to make the barrier material a certain minimum thickness means that there is less room in the trench for the copper material. Accordingly, the overall resistance of the conductive structure increases, as the barrier layer material is less conductive than copper. Efforts to form the barrier layers to ever decreasing thicknesses runs the risk that the barrier layers will not be formed as continuous films and that they will, therefore, not be able to perform at least some of their intended functions, e.g., they may not be able to effectively prevent migration of copper into unwanted areas, and the barrier layer may be incapable of serving, if need be, as a shunt in the case where the copper structure has degraded due to electromigration.

The present disclosure is directed to various methods of forming graphene liners and/or capping layers on copper-based conductive structures that may solve or at least reduce some of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to methods of forming graphene liners and/or capping layers on copper-based conductive structures. One illustrative method disclosed herein includes forming a trench/via in a layer of insulating material, forming a graphene liner layer in at least the trench/via, forming a copper-based seed layer on the graphene liner layer, depositing a bulk copper-based material on the copper-based seed layer so as to overfill the trench/via, and performing at least one chemical mechanical polishing process to remove at least excess amounts of the bulk copper-based material and the copper-based seed layer positioned outside of the trench/via to thereby define a copper-based conductive structure with a graphene liner layer positioned between the copper-based conductive structure and the layer of insulating material.

One illustrative device disclosed herein includes a layer of insulating material, a copper-based conductive structure positioned in a trench/via within the layer of insulating material and a graphene liner layer positioned between the copper-based conductive structure and the layer of insulating material.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1D depict one illustrative process flow for forming graphene liners on copper-based conductive structures; and

FIGS. 2-3 depict other illustrative process flows disclosed herein for forming graphene liners and/or capping layers on copper-based conductive structures.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to methods of forming graphene liners and/or capping layers on copper-based conductive structures. As will be readily apparent to those skilled in the art upon a complete reading of the present application, the present method is applicable to a variety of technologies, e.g., NFET, PFET, CMOS, etc., and is readily applicable to a variety of devices, including, but not limited to, ASIC's, logic devices, memory devices, etc. With reference to the attached drawings, various illustrative embodiments of the methods disclosed herein will now be described in more detail.

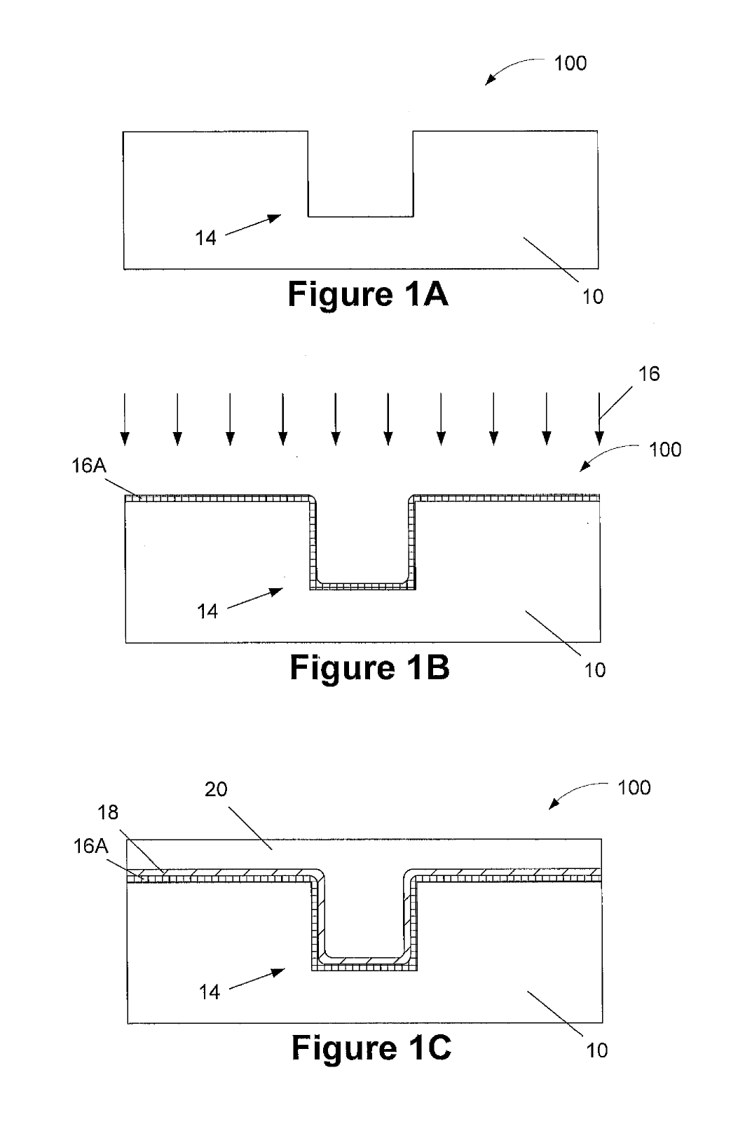

FIG. 1A is a simplified view of an illustrative integrated circuit device 100 at an early stage of manufacturing that is formed above a semiconducting substrate (not shown). The device 100 may be any type of integrated circuit device that employs any type of a conductive copper structure, such as a conductive line or via commonly found on integrated circuit devices. At the point of fabrication depicted in FIG. 1A, a trench/via 14 has been formed in the layer of insulating material 10 by performing known photolithography and etching techniques. The trench/via 14 is intended to be representative of any type of opening in any type of insulating material wherein a conductive copper structure may be formed. The trench/via 14 may be of any desired shape, depth or configuration. For example, in some embodiments, the trench/via 14 is a classic trench that does not extend to an underlying layer of material, such as the illustrative trench 14 depicted in FIG. 1A. In other embodiments, the trench/via 14 may be a through-hole type feature, e.g., a classic via, that extends all of the way through the layer of insulating material 10 and exposes an underlying layer of material or an underlying conductive structure, such as an underlying metal line. Thus, the shape, size, depth or configuration of the trench/via 14 should not be considered to be a limitation of the present invention.

The various components and structures of the device 100 may be initially formed using a variety of different materials and by performing a variety of known techniques. For example, the layer of insulating material 10 may be comprised of any type of insulating material, e.g., silicon dioxide, a low-k insulating material (k value less than 3), etc., it may be formed to any desired thickness and it may be formed by performing, for example, a chemical vapor deposition (CVD) process or spin-on deposition (SOD) process, etc.

Next, as shown in FIG. 1B, a graphene formation process 16 is performed to form a graphene liner layer 16A on the layer of insulating material 10 and in the trench 14. In one illustrative embodiment, the graphene liner layer 16A may have a thickness that falls within the range of about 0.3-2 nm. In one illustrative example, the graphene formation process 16 may be a spin-coating process or a spray coating process wherein graphene colloids are coated or sprayed on the exposed surfaces of the layer of insulating material 10 and thereafter allowed to dry so as to form the graphene liner layer 16A, which may be comprised of one or more monolayers of graphene. In one example, the process 16 may involve use of dilute chemically converted graphene that is air-sprayed onto the layer of insulating material 10, wherein the process may be performed at room temperature. In general, for relatively small-sized substrates, the graphene colloids may be sprayed on the layer of insulating material 10, while, for larger substrates, the colloids may be applied to the layer of insulating material 10 by performing a spin-coating process. Although not depicted in the drawings, in one illustrative embodiment, a layer of hexagonal boron nitride (HBN) may be sprayed on the layer of insulating material 10 prior to the formation of the graphene liner layer 16A. HBN generally has a crystalline structure that is the same as or similar to the crystalline structure of graphene. Such an HBN layer may have a thickness of about 1-3 nm. The HBN layer has a very high phonon frequency which may significantly reduce electron-phonon scattering, which would tend to be beneficial for very small copper interconnect structures. Reducing electron scattering in such copper interconnect structures would lower the resistivity of the conductive line or via.

Thereafter, as shown in FIG. 1C, a copper-based seed layer 18 is formed on the graphene liner layer 16A. In one example, the copper-based seed layer 18 may have a specifically targeted as-deposited thickness profile of about 10 nm or less. Next, an appropriate amount of bulk copper-based material 20, e.g., a layer of copper about 500 nm or so thick, is formed across the device 10 in an attempt to insure that the trench/via 14 is completely filled with copper. In an electroplating process, electrodes (not shown) are coupled to the copper seed layer 18 at the perimeter of the substrate and a current is passed through the copper seed layer 18 which causes the bulk copper material 20 to deposit and build on the copper seed layer 18. The copper-based material 18, 20 may be comprised of pure copper, or a copper alloy, including, for example, copper-aluminum, copper-cobalt, copper-manganese, copper-magnesium, copper-tin and copper-titanium, with alloy concentration ranging from 0.1 atomic percent to about 50 atomic percent based on the particular application. In some applications, the copper-based seed layer 18 may be omitted, and electroplated copper may be formed directly on the graphene layer.

FIG. 1D depicts the device 100 after at least one chemical mechanical polishing (CMP) process has been performed to remove excess bulk copper-based material 20, the copper-based copper seed layer 18 and the graphene liner layer 16A positioned outside of the trench/via 14 to thereby define a conductive copper-based structure 22. In this embodiment, the copper-based seed layer 18 is essentially merged into the bulk copper-based material 20, thus, the copper-based seed layer 18 is depicted in dashed lines in FIG. 1D. The device 100 may include a hard mask layer (not shown), e.g., a layer of silicon nitride, that was formed on the layer of insulating material 10 prior to the formation of the trench 14. If present, such a hard mask layer may act as a polish-stop layer during the CMP process.

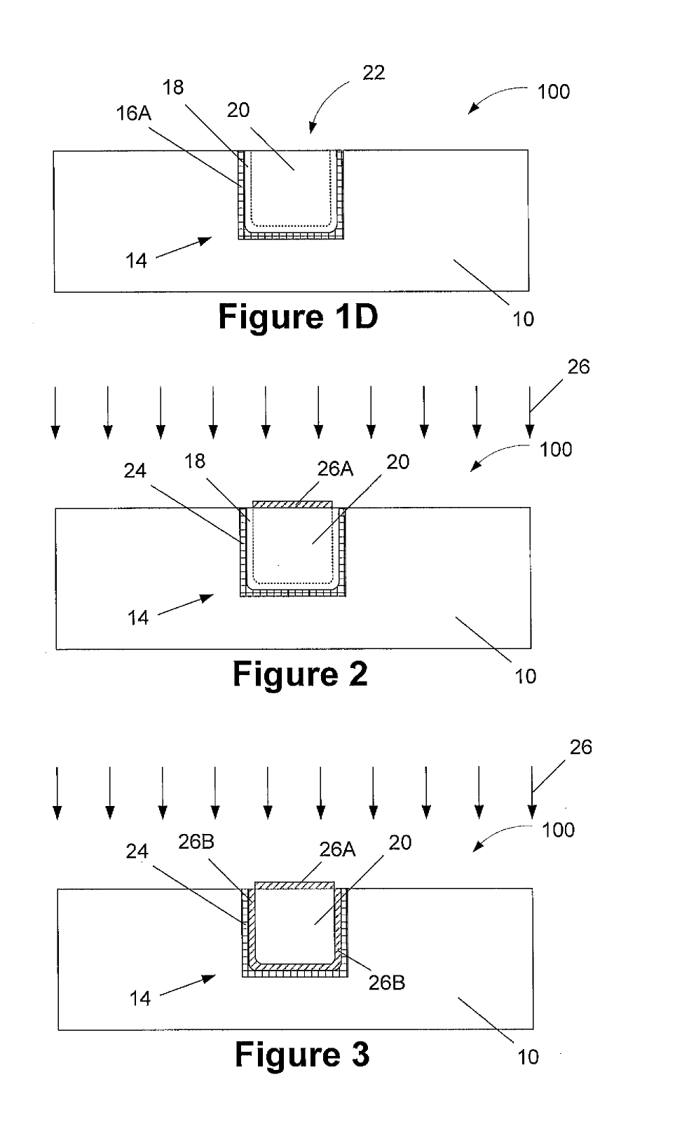

FIG. 2 depicts another illustrative embodiment disclosed herein. In FIG. 2, a traditional barrier layer 24 for copper-based structures, e.g., ruthenium, tantalum, etc., is formed instead of the graphene liner layer 16A depicted in FIGS. 1A-1D. That is, in the example depicted in FIGS. 1A-1D, the graphene liner layer 16A functions as a barrier layer and a traditional barrier layer 24 is not formed in the embodiment shown in FIG. 1D. If a traditional barrier layer 24 is used, it may be formed by performing a conformal PVD process using the appropriate metal targets. Thereafter, the copper seed layer 18 and the bulk carbon material 20 were formed as described above. Thereafter, the previously described CMP process was performed to remove excess materials positioned outside of the trench 14. Next, a selective graphene deposition process 26 was performed to selectively form a graphene cap layer 26A on the upper surface of the copper-based material 20. In one illustrative embodiment, the graphene cap layer 26A may have a thickness that falls within the range of about 0.3-2 nm. The selective deposition process 26 may, in one embodiment, be performed at a temperature greater than approximately 700-1000° C. using methane (CH₄). In general, within these temperature ranges, the methane thermally reacts with the copper-based structure 20 to form graphene on the copper material 20 as the methane decomposes into carbon (C) and hydrogen (H₂) to thereby form the graphene cap layer 26A shown in FIG. 2. The selective deposition process 26 may also be lower temperature (e.g., 300-400° C.) graphene formation processes, such as a plasma-enhanced CVD process or a rapid thermal/laser annealing process.

FIG. 3 depicts another illustrative embodiment, wherein the traditional barrier layer 24, copper seed layer 18 and the bulk copper material 20 has been formed as described above and a CMP process was performed to remove excess portions of these materials positioned outside of the trench 14. In this embodiment, the deposition process 26 is performed at such a temperature and for such a duration that the decomposed carbon atoms diffuse through the bulk copper-based material 20 and form a graphene liner layer 26B at the interface between the copper-based material 20 and the barrier layer 24.

The barrier liner layer 24 described above may be comprised of a variety of materials, such as, for example, tantalum, tantalum nitride, ruthenium, ruthenium alloys, cobalt, titanium, iridium, etc., and its thickness may vary depending upon the particular application. In some cases, more than one barrier liner layer may be formed in the trench/via 14. The barrier liner layer 24 may be formed by performing a physical vapor deposition (PVD) process, an ALD process, a CVD process or plasma-enhanced versions of such processes. In some applications, ruthenium or a ruthenium alloy may be employed as the barrier liner material because it bonds strongly with copper metal, which may improve the device's electromigration resistance. Cobalt or a cobalt alloy may also be employed as the barrier liner material since it also tends to bond very well with copper metal.

As will be appreciated by those skilled in the art after a complete reading of the present application, the use of the graphene liner and/or graphene cap layers disclosed herein may be very beneficial as it relates to the formation of conductive copper structures on integrated circuit devices. As noted above, the graphene liner and graphene cap layers disclosed above may be formed to very small thicknesses, thereby greatly assisting in scaling of conductive lines and via. Moreover, since graphene is highly conductive, even in very thin layers, it can serve the electrical shunting function if necessary.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1. A method, comprising:
forming a trench/via in a layer of insulating material;
forming a graphene liner layer in at least said trench/via;
forming a copper-based seed layer on said graphene liner layer;
depositing a bulk copper-based material on said copper-based seed layer so as to overfill said trench/via; and
performing at least one chemical mechanical polishing process to remove at least excess amounts of said bulk copper-based material and said copper-based seed layer positioned outside of said trench/via to thereby define a copper-based conductive structure with a graphene liner layer positioned between said copper-based conductive structure and said layer of insulating material.

2. The method of claim 1, further comprising forming a graphene cap layer on an upper surface of said copper-based conductive structure.

3. The method of claim 1, wherein, prior to forming graphene liner layer, the method further comprises forming a barrier liner layer above said layer of insulating material and in said trench/via and wherein forming said graphene liner layer comprises forming said graphene liner layer on said barrier liner layer in said trench/via.

4. The method of claim 3, wherein said barrier liner layer is comprised of one of tantalum, tantalum nitride or ruthenium.

5. The method of claim 1, wherein forming said graphene liner layer comprises performing a spin-coating process or a spray coating process to deposit graphene colloids so as to form said graphene liner layer in at least said trench/via.

6. A method, comprising:
forming a trench/via in a layer of insulating material;
depositing a copper-based material above said layer of insulating material so as to overfill said trench/via;
performing at least one chemical mechanical polishing process to remove at least excess amounts of said copper-based material positioned outside of said trench/via to thereby define a copper-based conductive structure; and
performing a selective graphene deposition process to form a graphene cap layer on an upper surface of said copper-based conductive structure.

7. The method of claim 6, wherein, prior to depositing said copper-based material, the method further comprises forming a barrier liner layer above said layer of insulating material and in said trench/via and wherein depositing said copper-based material comprises depositing said copper-based material on said barrier liner layer in said trench/via.

8. The method of claim 7, wherein said barrier liner layer is comprised of one of tantalum, tantalum nitride or ruthenium.

9. The method of claim 7, wherein performing said selective graphene deposition process further forms a graphene liner layer at an interface between said copper-based conductive structure and said barrier layer.

10. The method of claim 6, wherein said selective graphene deposition process is performed at a temperature within the range of 700-1000° C. in a process ambient comprising methane.

11. The method of claim 6, wherein said selective graphene deposition process is a plasma-enhanced chemical vapor deposition process or a rapid thermal/laser annealing process performed at a temperature within the range of 300-400° C.

12. A method, comprising:
forming a trench/via in a layer of insulating material;
forming a barrier liner layer above said layer of insulating material and in said trench/via;
depositing a copper-based material above said barrier liner layer so as to overfill said trench/via with said copper-based material;
performing at least one chemical mechanical polishing process to remove at least excess amounts of said copper-based material positioned outside of said trench/via to thereby define a copper-based conductive structure; and
performing a selective graphene deposition process to form a graphene cap layer on an upper surface of said copper-based conductive structure and a graphene liner layer at an interface between said copper-based conductive structure and said barrier liner layer.

13. The method of claim 12, wherein said barrier liner layer is comprised of one of tantalum, tantalum nitride or ruthenium.

14. The method of claim 12, wherein said selective graphene deposition process is performed at a temperature within the range of 700-1000° C. in a process ambient comprising methane.

15. The method of claim 12, wherein said selective graphene process is a plasma-enhanced chemical vapor deposition process or a rapid thermal/laser annealing process performed at a temperature within the range of 300-400° C.

16-20. (canceled)
